(19) United States
(12) Patent Application Publication
(10) Pub. No.: US 2016/0211146 A1
(43) Pub. Date: Jul. 21, 2016

(54) SEMICONDUCTOR MANUFACTURING DEVICE, MANAGEMENT METHOD THEREOF, AND MANUFACTURING METHOD OF SEMICONDUCTOR DEVICE

(71) Applicant: Renesas Electronics Corporation, Tokyo (JP)

(72) Inventors: Ayaka OKUMURA, Ibaraki (JP); Naohide HAMADA, Ibaraki (JP)

(21) Appl. No.: 14/925,099

(22) Filed: Oct. 28, 2015

(30) Foreign Application Priority Data
Jan. 21, 2015 (JP) 2015-009739

(51) Int. Cl. H01L 21/311; H01L 21/3105; H01L 21/02

(52) U.S. Cl. CPC H01L 21/31111; H01L 21/02274; H01L 21/31053

(57) ABSTRACT

Manufacturing yield of semiconductor device is improved by suppressing generation of foreign objects in a high-density plasma processing device. A high-density plasma CVD device includes an electrode, a guard ring surrounding an outer circumference of the electrode, an insulating member which is arranged over the guard ring and which surrounds the outer circumference of the electrode, and a plurality of spacers arranged between the guard ring and the insulating member. A height difference between an upper surface of the electrode and an upper surface of the insulating member is set to 0.05 to 0.25 mm.

### CROSS-REFERENCE TO RELATED APPLICATIONS

The disclosure of Japanese Patent Application No. 2015-009739 filed on Jan. 21, 2015 including the specification, drawings and abstract is incorporated herein by reference in its entirety.

### BACKGROUND

The present invention relates to a semiconductor manufacturing device, a management method thereof, and a manufacturing method of semiconductor device, which are preferably used for, for example, a processing device using a high-density plasma and manufacture of semiconductor device using the processing device.

Japanese Unexamined Patent Application Publication (Translation of PCT Application) No. 2004-511901 (Patent Document 1) describes a technique for improving temperature control of an edge ring supported by an edge ring chuck by supplying heat transfer gas such as helium between the edge ring chuck and a surface opposed to the edge ring chuck.

Further, Japanese Unexamined Patent Application Publication No. 2013-102236 (Patent Document 2) describes a technique for protecting an RF strap provided in a plasma processing device from plasma-generated radical by coating the RF strap with a flexible polymer or elastomer.

### SUMMARY

In a manufacturing process of semiconductor device, there are many processes that use a high-density plasma in, for example, chemical vapor deposition, (CVD), physical vapor deposition (PVD), etching, and sputtering. In a processing device that uses a high-density plasma (hereinafter referred to as a high-density plasma processing device), it is required to suppress dust generation in order not to degrade manufacturing yield of semiconductor device.

However, for example, in a high-density plasma CVD (High Density Plasma Chemical Vapor Deposition) device, when the plasma enters into a gap between an insulating member provided to prevent abnormal discharge of plasma around an electrode on which a semiconductor wafer is mounted and a rear surface of an outer circumferential portion of the semiconductor wafer, a problem occurs in which a coating is peeled from the rear surface of the outer circumference portion of the semiconductor wafer to an outer edge portion and many foreign objects are attached to a main surface of the semiconductor wafer.

The other purposes and the new features will become clear from the description of the present specification and the accompanying drawings.

According to an embodiment, a high-density plasma CVD device includes an electrode, a guard ring surrounding an outer circumference of the electrode, a insulating member which is arranged over the guard ring and which surrounds the outer circumference of the electrode, and a plurality of spacers arranged between the guard ring and the insulating member. A height difference between an upper surface of the electrode and an upper surface of the insulating member is set to 0.05 to 0.25 mm.

Further, according to an embodiment, a management method of a high-density plasma CVD device includes the steps of arranging a guard ring surrounding an outer circumference of the electrode to the outer circumference of the electrode, arranging an insulating member surrounding the outer circumference of the electrode over the guard ring, measuring a height difference between an upper surface of the electrode and an upper surface of the insulating member, and comparing a measured value of the height difference between the upper surface of the electrode and the upper surface of the insulating member with a management value. When the measured value is greater than a maximum value of the management value, a plurality of spacers are inserted between the guard ring and the insulating member.

Further, according to an embodiment, a manufacturing method of a semiconductor device includes the steps of forming a silicon nitride film on a main surface of a substrate, forming a trench in the substrate by sequentially etching the silicon nitride film and the substrate, forming a silicon oxide film over the silicon nitride film including inside of the trench by using a high-density plasma CVD device, and removing the silicon oxide film outside the trench by polishing a surface of the silicon oxide film. Here, the high-density plasma CVD device includes an electrode, a guard ring surrounding an outer circumference of the electrode, a insulating member which is arranged over the guard ring and which surrounds the outer circumference of the electrode, and a plurality of spacers arranged between the guard ring and the insulating member. A height difference between an upper surface of the electrode and an upper surface of the insulating member is set to 0.05 to 0.25 mm.

According to an embodiment, it is possible to suppress generation of foreign objects in a high-density plasma processing device and improve manufacturing yield of semiconductor device.

### BRIEF DESCRIPTION OF THE DRAWINGS

FIG. 1 is a main part schematic diagram showing an example of a high-density plasma CVD device according to an embodiment.

FIG. 2 is a main part cross-sectional view showing a structure of a stage portion provided in the high-density plasma CVD device according the embodiment.

FIG. 3 is a main part cross-sectional view showing, in an enlarged manner, an end portion of the stage portion provided in the high-density plasma CVD device according the embodiment and an outer circumferential portion of a semiconductor wafer.

FIG. 4 is a graphic diagram showing a relationship between the number of foreign objects over a main surface of the semiconductor wafer and a gap provided between an insulating member and a rear surface of the outer circumferential portion of the semiconductor wafer according the embodiment.

FIG. 5 is a main part perspective view showing the structure of the stage portion provided in the high-density plasma CVD device according the embodiment.

FIG. 6 is a flowchart showing a management process of the high-density plasma CVD device according to the embodiment.

FIG. 7 is a main part cross-sectional view showing a manufacturing process of a semiconductor device (element isolation) according to the embodiment.

FIG. 8 is a main part cross-sectional view showing a manufacturing process of the semiconductor device (element isolation) following FIG. 7.

FIG. 9 is a main part cross-sectional view showing a manufacturing process of the semiconductor device (element isolation) following FIG. 8.

FIG. 10 is a main part cross-sectional view showing a manufacturing process of the semiconductor device (element isolation) following FIG. 9.

FIG. 11 is a main part cross-sectional view showing a manufacturing process of the semiconductor device (element isolation) following FIG. 10.

FIG. 12 is a main part cross-sectional view showing a manufacturing process of the semiconductor device (element isolation) following FIG. 11.

FIG. 13 is a main part cross-sectional view showing a manufacturing process of the semiconductor device (element isolation) following FIG. 12.

FIG. 14 is a main part cross-sectional view showing a manufacturing process of the semiconductor device (element isolation) following FIG. 13.

FIG. 15 is a main part cross-sectional view showing a structure of an element isolation formed by using a high-density plasma CVD device discussed by the inventors.

FIG. 16 is a main part cross-sectional view showing, in an enlarged manner, an end portion of a stage portion provided in the high-density plasma CVD device discussed by the inventors and an outer circumferential portion of a semiconductor wafer.

### DETAILED DESCRIPTION

The following embodiment will be explained, divided into plural sections or embodiments, if necessary for convenience. Except for the case where it shows clearly in particular, they are not mutually unrelated and one has relationships such as a modification, details, and supplementary explanation of some or entire of another.

In the following embodiment, when referring to the number of elements, etc. (including the number, a numeric value, an amount, a range, etc.), they may be not restricted to the specific number but maybe greater or smaller than the specific number, except for the case where they are clearly specified in particular and where they are clearly restricted to a specific number theoretically.

Furthermore, in the following embodiment, it is needless to say that an element (including an element step etc.) is not necessarily indispensable, except for the case where it is clearly specified in particular and where it is considered to be clearly indispensable from a theoretical point of view, etc.

Further, when using words of “comprise A”, “composed of A”, “have A”, and “include A”, it is needless to say that elements other than A are not excluded, except for the case where it is clearly specified that there is only A, etc. Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

Still further, in some drawings used in the embodiment, hatching is used even in a plan view so as to make the drawings easy to see. Still further, components having the same function are denoted by the same reference symbols in principle throughout the drawings for describing the embodiments, and the repetitive description thereof is omitted. Hereinafter, the embodiment will be described in detail with reference to the drawings.

While the embodiment can be widely applied to a high-density process processing device using high-density plasma such as CVD, PCV, etching, or sputtering, as an example, a high-density plasma CVD device will be exemplified and the features and effects thereof will be described.

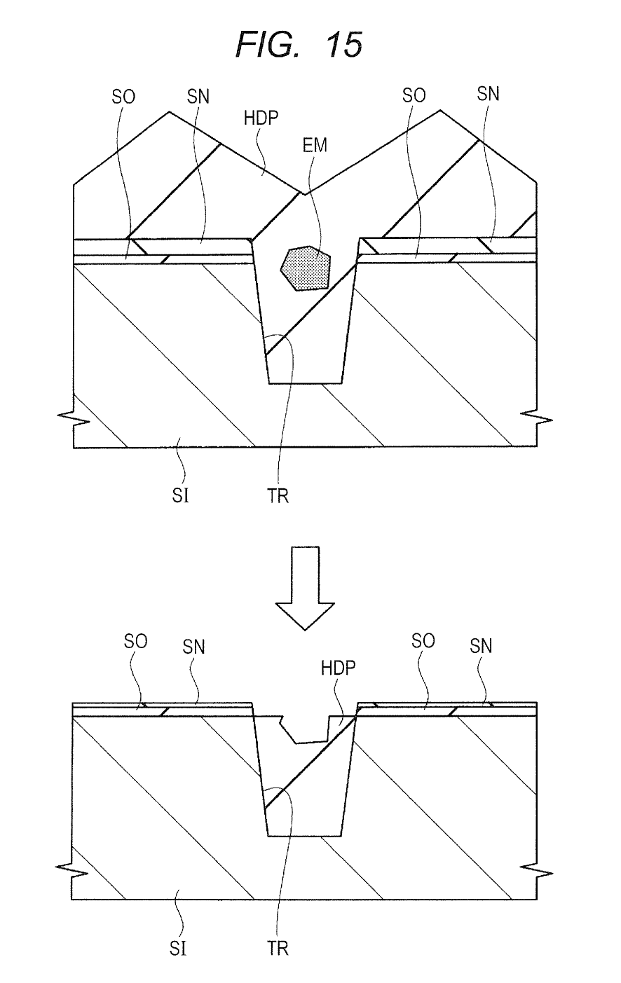

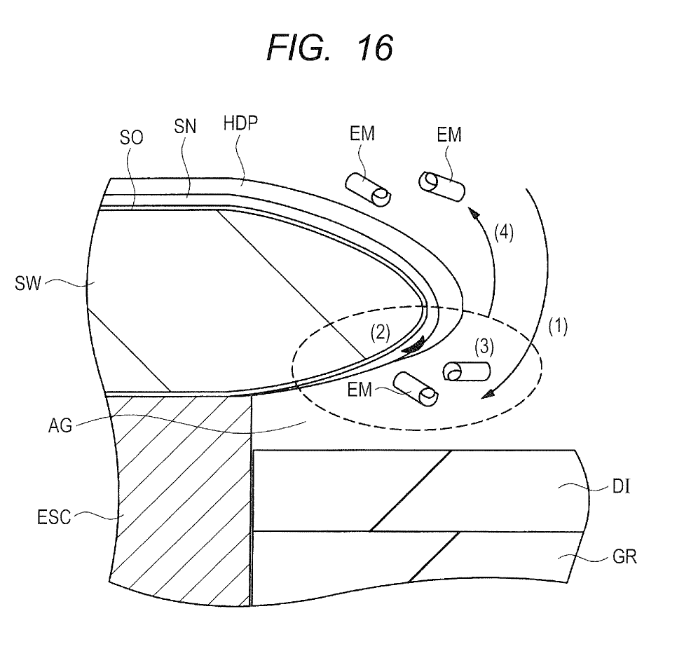

First, problems of a high-density plasma CVD device that is compared and discussed by the inventors will be described in detail with reference to FIGS. 15 and 16 because it is considered that the description of the problems will more clarify the high-density plasma CVD device of the embodiment. FIG. 15 is a main part cross-sectional view showing a structure of an element isolation formed by using the high-density plasma CVD device discussed by the inventors. FIG. 16 is a main part cross-sectional view showing, in an enlarged manner, an end portion of a stage portion provided in the high-density plasma CVD device discussed by the inventors and an outer circumferential portion of a semiconductor wafer.

A high-density plasma CVD method can generate plasma of, for example, about 10¹¹ particles/cm³ in a low vacuum atmosphere of about 1 Pa. Thereby, it is possible to realize film formation by combination of various gases or anisotropy control of ion. Further, the high-density plasma CVD method can bury an insulating material into inside of a narrow and deep trench by alternately repeating deposition (film formation) and sputter etching. For this reason, the high-density plasma CVD method is widely used for, for example, manufacturing an implanted-type shallow trench isolation that electrically isolates adjacent semiconductor elements from each other.

However, regarding the manufacture of the shallow trench isolation by using the high-density plasma CVD method, there are various technical problems described below.

As shown in FIG. 15, first, a silicon oxide film SO and a silicon nitride film SN are sequentially formed over a main surface (a circuit forming surface) of a semiconductor wafer SW formed of, for example, single crystal silicon, and thereafter, an isolation trench TR is formed in a desired region in the semiconductor wafer SW by sequentially processing the silicon nitride film SN, the silicon oxide film SO, and the semiconductor wafer SW by using a lithography method and a dry etching method.

Subsequently, a silicon oxide film HDP is formed over the main surface of the semiconductor wafer SW including inside of the isolation trench TR by using the high-density plasma CVD device.

As shown in FIG. 16, in the high-density plasma CVD device, the semiconductor wafer SW is mounted over an upper surface of an electrode ESC installed in a reaction chamber. A ring-shaped insulating member DI with a thickness of about 2 mm formed of, for example, ceramic is arranged around the electrode ESC in order to prevent abnormal discharge of plasma. The insulating member DI is not in contact with a rear surface (a surface opposite to the main surface) of an outer circumferential portion of the semiconductor wafer SW to prevent dust generation due to physical contact, and a gap AG of, for example, about 2 mm is generated between the insulating member DI and the rear surface of the outer circumferential portion of the semiconductor wafer SW. In other words, the upper surface of the insulating member DI is lower than the upper surface of the electrode ESC, so that there is a height difference between the upper surface of the insulating member DI and the upper surface of the electrode ESC and they do not form the same surface.

In this state, when the silicon oxide film HDP is formed by using high-density plasma, plasma is generated in the gap AG ((1) of FIG. 16) . While the high-density plasma CVD method forms the silicon oxide film HDP by alternately repeating deposition (film formation) and sputter etching as described above, the silicon nitride film SN is etched from the rear surface of the outer circumferential portion of the semiconductor wafer SW to an outer edge portion by the plasma generated in the gap AG when the sputter etching is performed ((2) of FIG. 16). The silicon nitride film SN is normally formed by a thermal CVD method, so that the thickness of the silicon nitride film SN formed from the rear surface of the outer circumferential portion of the semiconductor wafer SW to the outer edge portion is thinner than the thickness of the silicon nitride film SN formed over the main surface of the semiconductor wafer SW. Therefore, the silicon nitride film SN formed from the rear surface of the outer circumferential portion of the semiconductor wafer SW to the outer edge portion is easily etched. The silicon nitride film SN is etched, so that the silicon oxide film HDP is lifted off and film peeling occurs ((3) of FIG. 16). Of course, the etched silicon nitride film SN becomes a foreign object. Further, the peeled silicon oxide film HDP becomes a roll-shaped foreign object EM, is drawn to the electrode ESC, and is attached to the main surface of the semiconductor wafer SW ((4) of FIG. 16).

The roll-shaped foreign object EM attached to the main surface of the semiconductor wafer SW is mixed into the silicon oxide film HDP as shown in FIG. 15.

Thereafter, the silicon oxide film HDP is polished by a chemical mechanical polishing (CMP) method and the silicon oxide film HDP outside the isolation trench TR is removed, so that the shallow trench isolation is formed with the silicon oxide film HDP being remained only inside the isolation trench TR. However, if the roll-shaped foreign object EM is mixed into the silicon oxide film HDP, when the silicon oxide film HDP is polished, there is a risk that the roll-shaped foreign object EM is removed and a void defect is formed. Further, when the polishing is continued in a state in which the roll-shaped foreign object EM is removed, scratch damage (scar) occurs in the surface of the silicon oxide film HDP. Such void defect and scratch damage maybe a cause of, for example, a short circuit between gate electrodes of a field-effect transistor, so that the void defect and the scratch damage largely affect the yield rate of the semiconductor device.

Therefore, it is necessary to reduce generation of the roll-shaped foreign object EM by managing the gap AG between the insulating member DI and the rear surface of the outer circumferential portion of the semiconductor wafer SW and suppressing the generation of plasma in the gap AG.

### Embodiment

### High-Density Plasma CVD Device

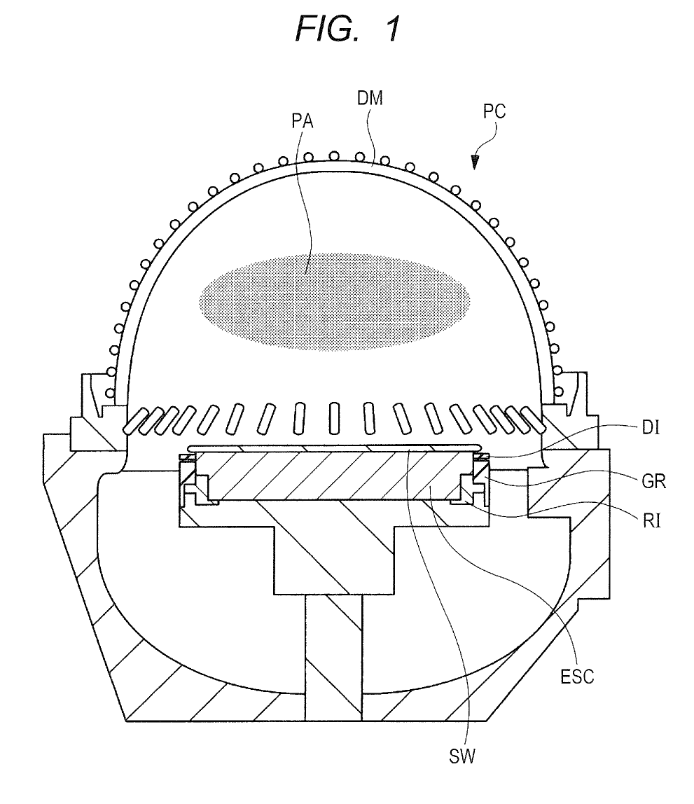

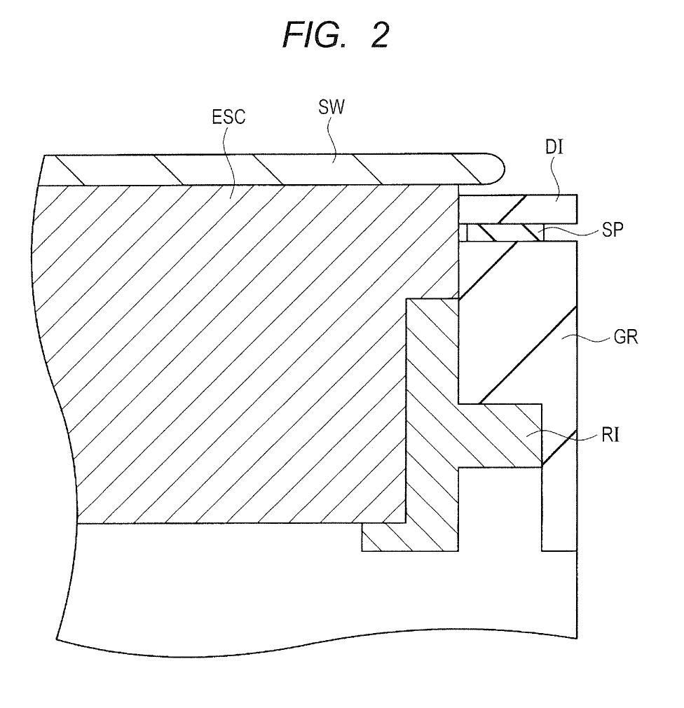

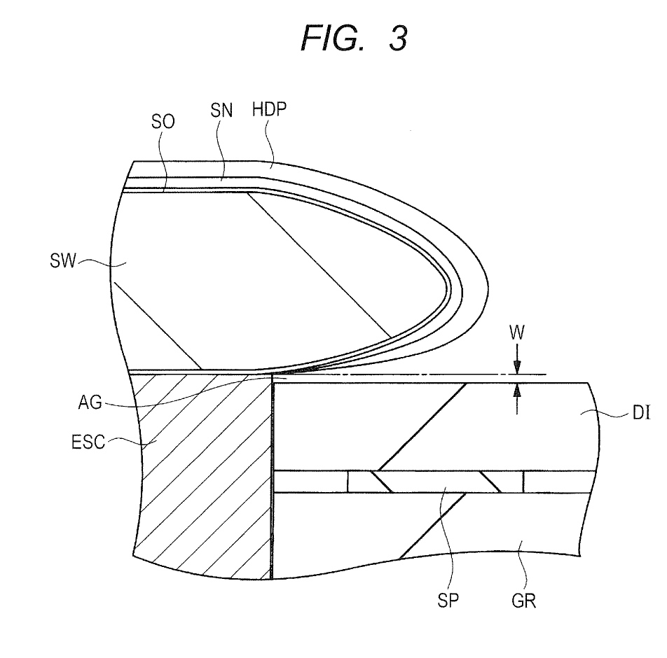

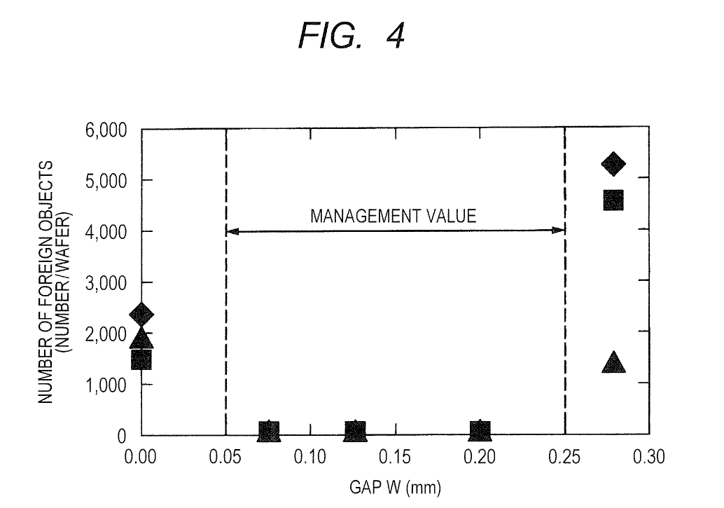

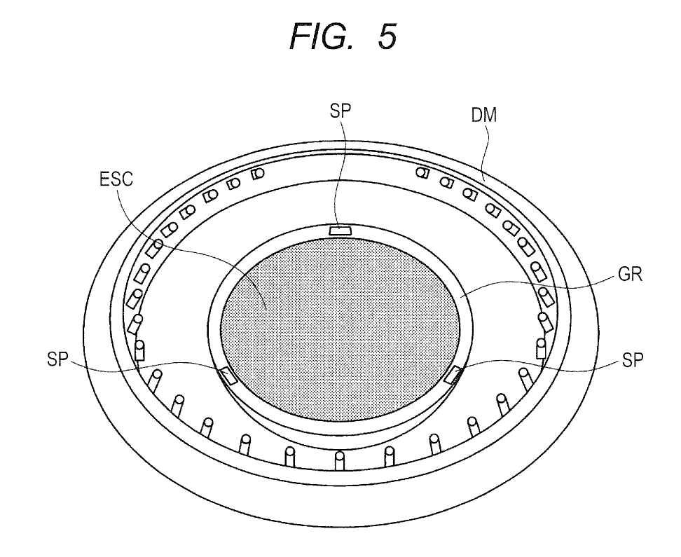

A high-density plasma CVD device according to an embodiment will be described with reference to FIGS. 1 to 5. FIG. 1 is a main part schematic diagram showing an example of the high-density plasma CVD device according to the embodiment. FIG. 2 is a main part cross-sectional view showing a structure of a stage portion provided in the high-density plasma CVD device according the embodiment. FIG. 3 is a main part cross-sectional view showing, in an enlarged manner, an end portion of the stage portion provided in the high-density plasma CVD device according the embodiment and an outer circumferential portion of a semiconductor wafer. FIG. 4 is a graphic diagram showing a relationship between the number of foreign objects over a main surface of the semiconductor wafer and a gap provided between an insulating member and a rear surface of the outer circumferential portion of the semiconductor wafer according the embodiment. FIG. 5 is a main part perspective view showing the structure of the stage portion provided in the high-density plasma CVD device according the embodiment.

As shown in FIG. 1, the inside of a reaction chamber (dome, chamber) DM of the high-density plasma CVD device PC is maintained at a low pressure by evacuating the reaction chamber, and the directionality of active species that reach the semiconductor wafer SW from a plasma generation region PA is stronger than that in other CVD devices (for example, a normal-pressure CVD device, a low-pressure CVD device, or a plasma CVD device). It is possible to alternately repeat deposition (film formation) and sputter etching by making a raw material gas into plasma by applying source electric power to the reaction chamber DM from a low-frequency power source and further performing sputter etching by applying a bias power (for example, the frequency is 13.56 MHz) to the semiconductor wafer SW from a high-frequency power source. Thereby, for example, it is possible to bury an insulating material into inside of a narrow and deep trench formed in the semiconductor wafer SW.

A stage on which the semiconductor wafer SW is mounted is installed below the plasma generation region PA. The stage include, for example, an electrode (electrostatic chuck) ESC, a conductive ring RI that is a base supporting the electrode ESC, a guard ring GR arranged so as to surround an outer circumference of the electrode ESC, and a ring-shaped flat insulating member (flat plate, disk) DI arranged over an upper surface of the guard ring GR so as to surround the outer circumference of the electrode ESC. Here, the ring-shape is an annular shape surrounded by a circular outer shape and a circular inner shape in plan view, and a circle that forms the inner shape is smaller than a circle that forms the outer shape.

The conductive ring RI is formed of, for example, aluminum (Al), and the guard ring GR is formed of, for example, alumina (Al₂O₃). The insulating member DI is arranged to prevent abnormal discharge of plasma, is formed of, for example, ceramic, and its thickness is about 2 mm. The semiconductor wafer SW is mounted over the upper surface of the electrode ESC to be closely attached to the electrode ESC.

Further, as shown in FIGS. 2 and 3, a plurality of spacers SP (tools that are put between the guard ring GR and the insulating member DI to secure a space) are arranged between the guard ring GR and the insulating member DI. The spacer SP is, for example, a flat plate with a uniform thickness and is formed of, for example, ceramic. The spacer is included in the insulating member DI in plan view and its planar shape is, for example, a rectangle about 1 cm on each side.

In this way, a plurality of spacers SP are provided between the guard ring GR and the insulating member DI, so that a width W of the gap AG between the insulating member DI and the rear surface of the outer circumferential portion of the semiconductor wafer SW (a height difference between the upper surface of the electrode ESC and the upper surface of the insulating member DI (a height difference between levels, a level difference)) is adjusted. Therefore, plasma is difficult to be generated in the gap AG. The width W of the gap AG is adjusted to, for example, a range between 0.05 mm and 0.25 mm. Thereby, it is possible to prevent the etching of the coating generated from the rear surface of the outer circumferential portion of the semiconductor wafer SW to the outer edge portion, so that it is possible to reduce the foreign objects attached to the main surface of the semiconductor wafer SW.

Specifically, as described with reference to FIG. 16, the high-density plasma CVD method forms the silicon oxide film HDP by alternately repeating deposition (film formation) and sputter etching, and if plasma is generated in the gap AG when the sputter etching is performed, the silicon nitride film SN is etched from the rear surface of the outer circumferential portion of the semiconductor wafer SW to the outer edge portion by the generated plasma. The silicon nitride film SN is etched, so that the silicon oxide film HDP is lifted off and film peeling occurs. Of course, the etched silicon nitride film SN becomes a foreign object. Further, the peeled silicon oxide film HDP becomes a roll-shaped foreign object EM, is drawn to the electrode ESC, and is attached to the main surface of the semiconductor wafer SW.

However, in the present embodiment, plasma is difficult to be generated in the gap AG, so that the etching of the silicon nitride film SN does not proceed from the rear surface of the outer circumferential portion of the semiconductor wafer SW to the outer edge portion. Therefore, it is possible to prevent the film peeling of the silicon oxide film HDP due to the etching of the silicon nitride film SN. Thereby, it is possible to reduce the generation of the roll-shaped foreign objects EM due to the film peeling of the silicon oxide film HDP.

FIG. 4 is a graphic diagram showing a relationship between the number of foreign objects over the main surface of the semiconductor wafer SW and the width W of the gap AG between the insulating member DI and the rear surface of the outer circumferential portion of the semiconductor wafer SW (the height difference between the upper surface of the electrode ESC and the upper surface of the insulating member DI). The number of foreign objects on the vertical axis is the number of foreign objects, the size of which is 0.1 μm or more. As shown in FIG. 3, the silicon nitride film SN is formed over the main surface of the semiconductor wafer SW by the thermal CVD method and further the silicon oxide film HDP is formed over the silicon nitride film SN by the high-density plasma CVD method. Thereafter, the number of foreign objects over the main surface of the semiconductor wafer SW is counted.

As shown in FIG. 4, when the width W of the gap AG is set to 0.05 to 0.25 mm, the number of foreign objects sharply decreases to about 0 objects/wafer. On the other hand, when the width W of the gap AG is 0.00 mm, the number of foreign objects increases to about 1,500 to 2,500 objects/wafer. It is considered that this is because the rear surface of the semiconductor wafer SW and the insulating member DI physically come into contact with each other and the foreign objects are generated. When the width W of the gap AG is greater than 0.25 mm, the number of foreign objects increases to about 1,000 to 5,000 objects/wafer. It is considered that this is because, as described above, the plasma is generated in the gap AG between the insulating member DI and the rear surface of the outer circumferential portion of the semiconductor wafer SW, the silicon nitride film SN is etched from the rear surface of the outer circumferential portion of the semiconductor wafer SW to the outer edge portion, the silicon oxide film HDP is lifted off and film peeling occurs, and the roll-shaped foreign objects EM are generated.

As described above, when the width W of the gap AG between the insulating member DI and the rear surface of the outer circumferential portion of the semiconductor wafer SW (the height difference between the upper surface of the electrode ESC and the upper surface of the insulating member DI) is set to, for example, 0.05 to 0.25 mm, it is possible to reduce the number of foreign objects over the main surface of the semiconductor wafer SW. Thereby, it is possible to improve the manufacturing yield of the semiconductor device.

As shown in FIG. 5, the spacer SP is placed at three positions over the upper surface of the guard ring GR arranged around the electrode ESC and the three spacers SP are arranged at positions corresponding to vertexes of a regular triangle in top view, respectively. Thereby, it is possible to stably arrange the insulating member DI. Although three spacers SP are used in the embodiment, the number of spacers SP is not limited to this, and four or more spacers may be used as long as the insulating member DI can be stably arranged over the upper surface of the guard ring GR.

### Management Method of High-Density Plasma CVD Device

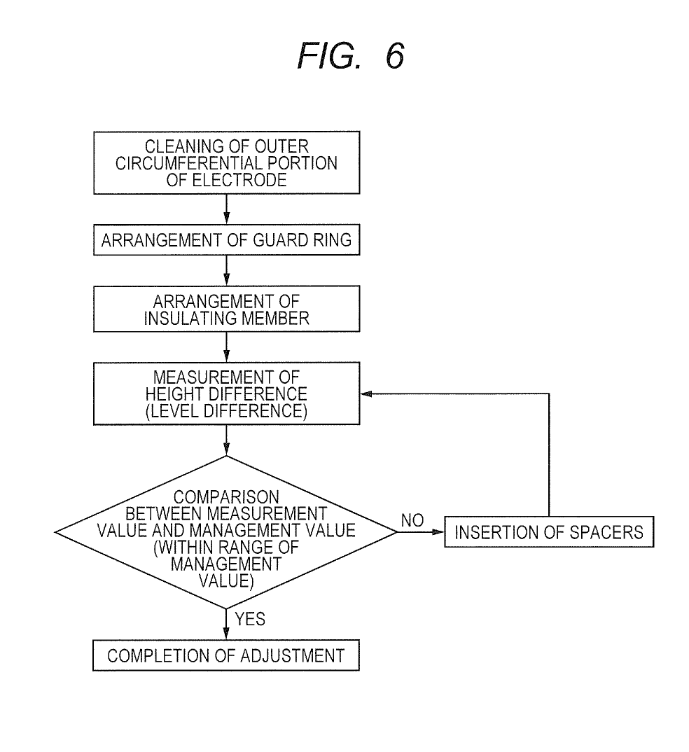

A management method of the high-density plasma CVD device according to the embodiment will be described with reference to FIG. 6. FIG. 6 is a flowchart showing a management process of the high-density plasma CVD device according to the embodiment. For the structure of the high-density plasma CVD device PC, refer to FIGS. 1 to 3.

The width W of the gap AG between the insulating member DI and the rear surface of the outer circumferential portion of the semiconductor wafer SW (the height difference between the upper surface of the electrode ESC and the upper surface of the insulating member DI) is adjusted by inserting a plurality of spacers SP between the guard ring GR and the insulating member DI, for example, when regular maintenance of the high-density plasma CVD device PC is performed. In other words, the width W of the gap AG is adjusted by using a plurality of spacers SP so that a measurement value of the height difference between the upper surface of the electrode ESC and the upper surface of the insulating member DI in a direction perpendicular to the upper surface of the electrode ESC is within a management value.

For example, as shown in FIG. 6, when regular maintenance of the high-density plasma CVD device PC is performed, the outer circumference portion of the electrode ESC is cleaned, and thereafter the guard ring GR is arranged around the electrode ESC, and further the insulating member DI is arranged over the upper surface of the guard ring GR.

Subsequently, the height difference between the upper surface of the electrode ESC and the upper surface of the insulating member DI is measured. When the value measured at this time is greater than a maximum value (for example, 0.25 mm) of the management value, a plurality of spacers SP are inserted between the guard ring GR and the insulating member DI, and the height difference between the upper surface of the electrode ESC and the upper surface of the insulating member DI is adjusted so that the height difference between the upper surface of the electrode ESC and the upper surface of the insulating member DI is within a range of the management value (for example, 0.05 to 0.25 mm). Thereby, it is possible to adjust the width W of the gap AG between the insulating member DI and the rear surface of the outer circumferential portion of the semiconductor wafer SW.

The measurement of the height difference between the upper surface of the electrode ESC and the upper surface of the insulating member DI and the insertion of the spacers SP are not limited to when the regular maintenance of the high-density plasma CVD device PC is performed, but maybe performed when a component is replaced or many foreign objects are generated.

Manufacturing Method of Semiconductor Device

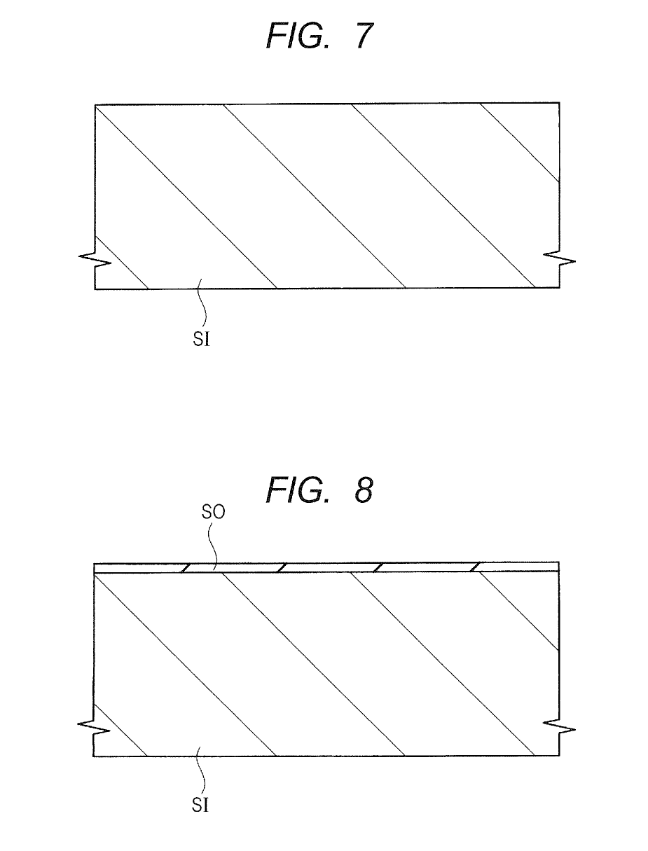

A manufacturing method of the element isolation formed in the main surface of the semiconductor wafer according to the present embodiment will be described in a process order with reference to FIGS. 7 to 14. FIGS. 7 to 14 are main part cross-sectional views showing a manufacturing process of the semiconductor device (element isolation) according to the embodiment.

Here, as an example, a case in which the high-density plasma CVD device PC described above is used in the manufacturing process of the element isolation will be described. As an element isolation that electrically isolates adjacent semiconductor elements from each other, for example, there is an implanted-type shallow trench isolation where an insulating material is buried inside an isolation trench with a depth of about 0.2 to 0.4 μm. The shallow trench isolation has advantages that flatness is good and an element isolation region can be reduced as compared with LOCOS (Local Oxidation of Silicon) isolation which is a typical element isolation, so that the shallow trench isolation is often used for manufacturing semiconductor devices of 0.18 μm process generation or later.

First, as shown in FIG. 7, a semiconductor substrate SI (in this stage, a thin plate of a semiconductor having an approximately circular shape in plan view, which is referred to as a semiconductor wafer) formed of, for example, single crystal silicon whose specific resistance is about 1 to 10 Ωcm is prepared.

Subsequently, as shown in FIG. 8, a thermal oxidation treatment is performed on the semiconductor substrate SI at a temperature of, for example, about 850° C. and the silicon oxide film SO is formed over the main surface of the semiconductor substrate SI. The thickness of the silicon oxide film SO is, for example, about 10 to 20 nm. The silicon oxide film SO is formed in order to reduce stress that is applied to the semiconductor substrate SI when the insulating material buried inside the isolation trench is densified (baked and tightened) in a later process.

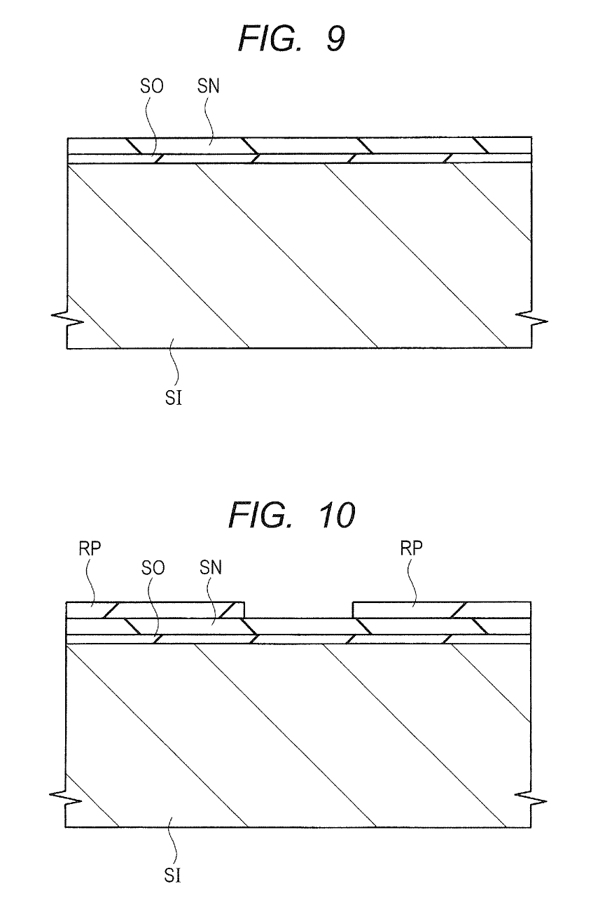

Subsequently, as shown in FIG. 9, a protective film, for example, the silicon nitride film SN, is formed over the silicon oxide film SO by, for example, a thermal CVD method. The thickness of the silicon nitride film SN is, for example, about 50 to 100 nm. The silicon nitride film SN has characteristic of difficult to be oxidized, so that the silicon nitride film SN is used as a mask that prevents oxidation of a surface of the semiconductor substrate SI (active region) under the silicon nitride film SN.

Subsequently, as shown in FIG. 10, a resist pattern RP is formed by a lithography method.

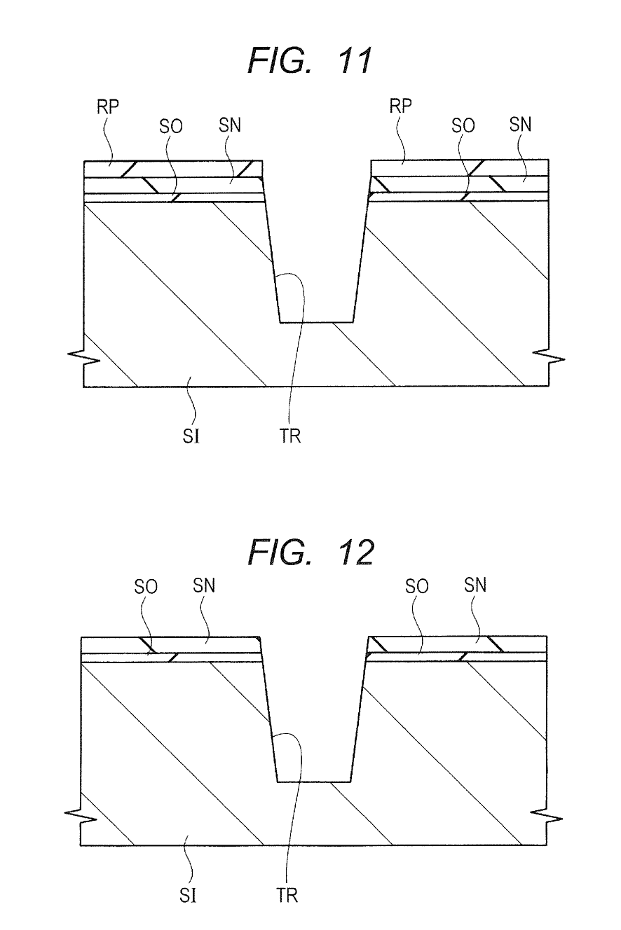

Subsequently, as shown in FIG. 11, the silicon nitride film SN and the silicon oxide film SO that are exposed from the resist pattern RP are removed by the dry etching method, and thereafter, the isolation trench TR with a depth of about 0.3 μm is formed in the semiconductor substrate SI by further processing the semiconductor substrate SI by the dry etching method.

Subsequently, as shown in FIG. 12, the resist pattern RP is removed. Subsequently, although not shown in the drawings, in order to remove a damage layer generated on an inner wall of the isolation trench TR by the dry etching method, the thermal oxidation treatment is performed on the semiconductor substrate SI at a temperature of, for example, about 1,000° C. to form a silicon oxide film with a thickness of, for example, about 10 nm on the inner wall of the isolation trench TR. At this time, a silicon oxynitride film can be formed on the inner wall of the isolation trench TR by performing thermal treatment in an atmosphere including oxygen and nitrogen. In this case, it is possible to further reduce the stress that is applied to the semiconductor substrate SI when the insulating material buried inside the isolation trench TR is densified in a later process. It is possible to form a silicon nitride film by a CVD method instead of the aforementioned method where the heat treatment is performed in an atmosphere including oxygen and nitrogen. Also in this case, it is possible to obtain the same effect.

Subsequently, as shown in FIG. 13, the silicon oxide film HDP is formed over the main surface of the semiconductor substrate SI including inside of the isolation trench TR by the high-density plasma CVD method. The silicon oxide film HDP is formed to be thicker than the depth of the isolation trench TR (for example, about 0.3 μm) and the silicon oxide film HDP with a thickness of, for example, about 0.5 to 0.6 μm is formed over the silicon nitride film SN. The thickness of the silicon oxide film HDP here is a thickness from the upper surface of the silicon nitride film SN to the highest upper surface of the silicon oxide film HDP.

The silicon oxide film HDP is formed by using the high-density plasma CVD device PC shown in FIGS. 1 to 3.

The semiconductor wafer SW is mounted over the upper surface of the electrode ESC provided in the reaction chamber DM so that the upper surface of the electrode ESC and the rear surface of the semiconductor wafer SW face each other. Although the insulating member DI arranged around the electrode ESC and the rear surface of the semiconductor wafer SW are not in contact with each other, it is possible to suppress generation of plasma in the gap AG between the insulating member DI and the rear surface of the outer circumferential portion of the semiconductor wafer SW by managing the height difference between the upper surface of the electrode ESC and the upper surface of the insulating member DI. The width W of the gap AG between the insulating member DI and the rear surface of the outer circumferential portion of the semiconductor wafer SW (the height difference between the upper surface of the electrode ESC and the upper surface of the insulating member DI) is controlled to, for example, 0.05 mm to 0.25 mm. Thereby, it is possible to suppress the film peeling which is generated when the silicon oxide film HDP is formed and which is due to the etching of the silicon nitride film SN and the liftoff of the silicon oxide film HDP, so that it is possible to reduce the generation of the roll-shaped foreign objects EM shown in FIG. 16.

The silicon oxide film HDP is formed by alternately repeating deposition (film formation) and sputter etching. For example, it is possible to bury the silicon oxide film HDP inside the isolation trench TR without the silicon oxide film HDP being an overhung shape by alternately repeating a plurality of times deposition of a silicon oxide film using monosilane (SiH₄) gas, oxygen (O₂) gas, and helium (He) gas and sputter etching using nitrogen trifluoride (NF₃) gas.

Subsequently, to improve the film quality of the silicon oxide film HDP, heat treatment is performed on the semiconductor substrate SI to densify the silicon oxide film HDP.

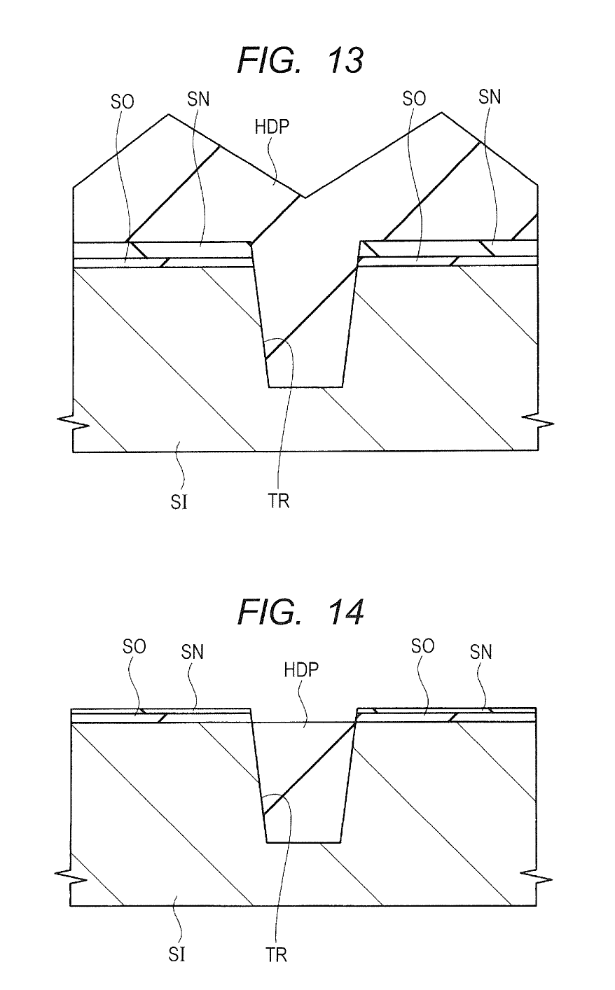

Subsequently, as shown in FIG. 14, the silicon oxide film HDP is polished by the CMP method using the silicon nitride film SN as a stopper and the silicon oxide film HDP outside the isolation trench TR is removed, so that the silicon oxide film HDP is remained only inside the isolation trench TR and an implanted-type shallow trench isolation whose surface is flattened is formed.

It is possible to reduce foreign objects generated when the silicon oxide film HDP is formed by using the high-density plasma CVD device PC, that is, for example, the roll-shaped foreign objects EM shown in FIG. 16, so that it is also possible to reduce the roll-shaped foreign objects EM mixed into the silicon oxide film HDP. Therefore, when the silicon oxide film HDP is polished, it is possible to suppress the generation of the void defect and the scratch damage due to the roll-shaped foreign objects EM.

As described above, according to the embodiment, the width W of the gap AG between the insulating member DI arranged around the electrode ESC provided in the high-density plasma CVD device PC and the rear surface of the outer circumferential portion of the semiconductor wafer SW (the height difference between the upper surface of the electrode ESC and the upper surface of the insulating member DI) is set to, for example, 0.05 to 0.25 mm by using a plurality of spacers SP. However, in the present embodiment, plasma is difficult to be generated in the gap AG, so that the etching of the silicon nitride film SN does not proceed from the rear surface of the outer circumferential portion of the semiconductor wafer SW to the outer edge portion. Therefore, it is possible to prevent the film peeling of the silicon oxide film HDP due to the etching of the silicon nitride film SN. As a result, the generation of foreign objects due to the etching of the silicon nitride film SN and the generation of the roll-shaped foreign objects EM due to the film peeling of the silicon oxide film HDP are reduced, so that it is possible to improve the manufacturing yield of the semiconductor device.

While the invention made by the inventors has been specifically described based on the embodiment, it is needless to say that the present invention is not limited to the embodiment and may be variously modified within the scope of the invention.

For example, in the embodiment described above, a case is described in which the embodiment is applied to a forming process of the implanted-type shallow trench isolation where the isolation trench is buried with a film formed by the high-density plasma CVD method. However, the embodiment can be applied to any manufacturing process of semiconductor device in which a level difference portion and a concave portion are buried with a film formed by the high-density plasma CVD method.

Further, for example, in the embodiment described above, the high-density plasma CVD method is described. However, the embodiment is not limited to the high-density plasma CVD method, and the embodiment can be applied to a processing device using high-density plasma in PCV, etching, sputtering, and the like. Further, the embodiment is not limited to the high-density plasma, but may be applied to CVD, PCV, etching, sputtering, and the like which use plasma.

What is claimed is:

1. A semiconductor manufacturing device that performs processing using plasma on a semiconductor wafer mounted over an upper surface of an electrode, the semiconductor manufacturing device comprising:
the electrode;
a guard ring formed of an insulating material surrounding an outer circumference of the electrode;
a member which is arranged over the guard ring and which is formed of the insulating material surrounding the outer circumference of the electrode; and
a plurality of spacers formed of an insulating material arranged between the guard ring and the member,
wherein a height difference between the upper surface of the electrode and an upper surface of the member is adjusted by the spacers.

2. The semiconductor manufacturing device according to claim 1,
wherein three spacers are arranged over the guard ring so that the spacers are respectively arranged at vertexes of a regular triangle in plan view.

3. The semiconductor manufacturing device according to claim 1,
wherein the member is a flat plate having an annular shape surrounded by a circular outer shape and a circular inner shape in plan view, and
wherein the spacers are included between the outer shape and the inner shape in plan view.

4. The semiconductor manufacturing device according to claim 1,
wherein the height difference between the upper surface of the electrode and the upper surface of the member is 0.05 to 0.25 mm.

5. The semiconductor manufacturing device according to claim 1,
wherein the spacers are formed of ceramic.

6. A management method of a semiconductor manufacturing device that performs processing using plasma on a semiconductor wafer mounted over an upper surface of an electrode, the management method comprising the steps of:
(a) arranging a guard ring formed of an insulating material surrounding an outer circumference of the electrode to the outer circumference of the electrode;
(b) arranging a member formed of the insulating material surrounding the outer circumference of the electrode over the guard ring;
(c) measuring a height difference between the upper surface of the electrode and an upper surface of the member;
(d) comparing a measured value of the height difference between the upper surface of the electrode and the upper surface of the member with a management value; and
(e) inserting a plurality of spacers formed of an insulating material between the guard ring and the member when the measured value is greater than a maximum value of the management value.

7. The management method of the semiconductor manufacturing device according to claim 6,
wherein the management value is 0.05 to 0.25 mm.

8. A manufacturing method of a semiconductor device, the manufacturing method comprising the steps of:
(a) forming a first insulating film on a main surface of a substrate;
(b) forming a trench in the substrate by sequentially etching the first insulating film and the substrate;
(c) forming a second insulating film over the first insulating film including inside of the trench by using a plasma CVD device; and
(d) removing the second insulating film outside the trench by polishing a surface of the second insulating film by a CMP method,
wherein the plasma CVD device used in the step (c) includes
an electrode,
a guard ring formed of an insulating material surrounding an outer circumference of the electrode,
a member which is arranged over the guard ring and which is formed of the insulating material surrounding the outer circumference of the electrode, and
a plurality of spacers formed of an insulating material arranged between the guard ring and the member, and
wherein a height difference between an upper surface of the electrode and an upper surface of the member is adjusted by the spacers.

9. The manufacturing method of the semiconductor device according to claim 8,
wherein three spacers are arranged over the guard ring so that the spacers are respectively arranged at vertexes of a regular triangle in plan view.

10. The manufacturing method of the semiconductor device according to claim 8,
wherein the member is a flat plate having an annular shape surrounded by a circular outer shape and a circular inner shape in plan view, and
wherein the spacers are included between the outer shape and the inner shape in plan view.

11. The manufacturing method of the semiconductor device according to claim 8,
wherein the height difference between the upper surface of the electrode and the upper surface of the member is 0.05 to 0.25 mm.

12. The manufacturing method of the semiconductor device according to claim 8,
wherein the spacers are formed of ceramic.
